(19) United States
(12) Patent Application Publication
(10) Pub. No.: US 2026/0148879 A1
(43) Pub. Date: May 28, 2026

(54) METHOD OF MANUFACTURING MULTICORE CABLE AND MULTICORE CABLE

(71) Applicant: Sumitomo Electric Industries, Ltd., Osaka (JP)

(72) Inventors: Narumi YOSHIDA, Tochigi (JP); Masamichi YAMAMOTO, Tochigi (JP); Takami SAGISAKA, Tochigi (JP); Shiho HATTORI, Tochigi (JP)

(73) Assignee: Sumitomo Electric Industries, Ltd., Osaka (JP)

(21) Appl. No.: 19/396,500

(22) Filed: Nov. 21, 2025

(30) Foreign Application Priority Data
Nov. 22, 2024 (JP) 2024-203772

(51) Int. Cl. H01B 7/00; H05K 1/18

(52) U.S. Cl. CPC H01B 7/0009; H05K 1/181; H05K 2201/10356; H05K 2201/10984

(57) ABSTRACT

A method of manufacturing a multicore cable. The multicore cable includes a plurality of electrical wires and a substrate. The electrical wires each include a conductor, a covering, and an exposed portion. The substrate includes a first surface provided with a plurality of terminals each corresponding to a respective one of the electrical wires. Heights of top portions of the exposed portions are not uniform. The method includes: arranging the exposed portions and solder on the plurality of terminals; and connecting the plurality of terminals and the exposed portions corresponding to the plurality of terminals to each other collectively by, while placing a flexible member against the exposed portions and pressing the flexible member toward the substrate, performing soldering by heating the conductors by a non-contact method and melting the solder.

### CROSS REFERENCE TO RELATED APPLICATIONS

This application claims priority based on Japanese Patent Application No. 2024-203772 filed on Nov. 22, 2024, and the entire contents of the Japanese patent application are incorporated herein by reference.

### TECHNICAL FIELD

The present disclosure relates to a method of manufacturing a multicore cable and a multicore cable.

### BACKGROUND

JP2014-17130A discloses a multi-core cable assembly in which a plurality of cables having different diameters are connected to a connection member.

### SUMMARY

A method of manufacturing a multicore cable according to an embodiment of the present disclosure is a method of manufacturing a multicore cable including a plurality of electrical wires and a substrate, the plurality of electrical wires each including a conductor, a covering configured to cover the conductor, and an exposed portion at which the conductor is exposed as a result of the covering being removed, the substrate including a first surface provided with a plurality of terminals each corresponding to a respective one of the plurality of electrical wires, and heights of top portions of the exposed portions each arranged on a corresponding one of the terminals being not uniform when the substrate is placed on a horizontal surface such that the first surface faces upward. The method includes arranging the exposed portions and solder on the plurality of terminals, and connecting the plurality of terminals and the exposed portions of the plurality of electrical wires corresponding to the plurality of terminals to each other collectively by, while placing a flexible member against the exposed portions and pressing the flexible member toward the substrate, performing soldering by heating the conductors by a non-contact method and melting the solder.

### BRIEF DESCRIPTION OF THE DRAWINGS

FIG. 1 is a schematic view of a multicore cable according to an embodiment of the present disclosure.

FIG. 2 is a cross-sectional view of a cable.

FIG. 3 is a plan view of a connecting portion between electrical wires and a substrate.

FIG. 4 is a diagram showing a process of a method of manufacturing a multicore cable according to an embodiment of the present disclosure.

FIG. 5 is a diagram showing an example of a process of pressing exposed portions by a flexible member in a connecting process.

FIG. 6 is a diagram showing a connecting process in a method of manufacturing according to a first comparative example.

FIG. 7 is a diagram showing a connecting process in a method of manufacturing according to a second comparative example.

FIG. 8 is a diagram showing a modification of a configuration to which a method of manufacturing of the present disclosure is applied.

FIG. 9 is a diagram showing a modification of a configuration to which a method of manufacturing of the present disclosure is applied.

FIG. 10 is a diagram showing a modification of a configuration to which a method of manufacturing of the present disclosure is applied.

FIG. 11 is a diagram showing a modification of a configuration to which a method of manufacturing of the present disclosure is applied.

### DETAILED DESCRIPTION

When a plurality of electrical wires are connected to a substrate, a method of connecting the plurality of electrical wires by simultaneously pressing and heating the plurality of electrical wires by a pulse heating method may be adopted. However, when a plurality of electrical wires having different diameters are connected, or when a substrate has recesses and projections, steps, or the like, some of the electrical wires and a heater chip may not be sufficiently in contact with each other, and a connection failure may occur.

An object of the present disclosure is to provide a method of manufacturing a multicore cable that can simultaneously connect a plurality of electrical wires to a substrate in a case where diameters of the plurality of electrical wires are not uniform or the like.

### Description of Embodiments of Present Disclosure

First, embodiments of the present disclosure will be listed and described.

(1) A method of manufacturing a multicore cable according to an embodiment of the present disclosure is a method of manufacturing a multicore cable including a plurality of electrical wires and a substrate, in which the plurality of electrical wires each include a conductor, a covering configured to cover the conductor, and an exposed portion at which the conductor is exposed as a result of the covering being removed, in which the substrate has a first surface provided with a plurality of terminals each corresponding to a respective one of the plurality of electrical wires, and in which heights of top portions of the exposed portions each arranged on a corresponding one of the terminals are not uniform when the substrate is placed on a horizontal surface such that the first surface faces upward. The method includes arranging the exposed portions and solder on the plurality of terminals, and connecting the plurality of terminals and the exposed portions of the plurality of electrical wires corresponding to the plurality of terminals to each other collectively by, while placing a flexible member against the exposed portions and pressing the flexible member toward the substrate, performing soldering by heating the conductors by a non-contact method and melting the solder.

In a pulse heating method in which heating is performed while applying pressure using a heater chip, when heights of top portions of electrical wires to be connected are not uniform, a connection failure is likely to occur in a portion having a relatively low height. When a flexible member is interposed between the heater chip and the electrical wires in order to uniformly press the electrical wires having different heights, the takt time increases because of low thermal conductivity of the flexible member. By heating the electrical wires by the non-contact method without using the flexible member while pressing the electrical wires by the flexible member, the electrical wires having non-uniform heights can be connected to the terminals collectively in a good manner.

(2) In the above (1), the plurality of electrical wires may include a plurality of electrical wires differing from each other in terms of outer diameters of the conductors. According to the above method of manufacturing, electrical wires having different diameters can be connected to the substrate collectively.

(3) In the above (1), the first surface of the substrate may include a first region and a second region differing from each other in terms of heights of the first region and the second region from the horizontal surface. The terminals may be provided in each of the first region and the second region. In the connecting, the exposed portions of the plurality of electrical wires each corresponding to a respective one of the terminals may be collectively connected to the terminals provided in the first region and the terminals provided in the second region. According to the above method of manufacturing, even when there is a step or an inclination on a surface of the substrate on which the terminal are provided, the plurality of electrical wires can be connected to the terminals collectively.

(4) In any one of the above (1) to (3), the non-contact method may be heating with hot air. The heating with hot air facilitates control of the heating range, and damage to surrounding connection members and the coverings of the electrical wires, and the like is easily avoided.

(5) In any one of the above (1) to (4), heating of each of the exposed portions by the non-contact method may be performed by heating a first portion of each of the electrical wires extending from the exposed portion in a first direction, and allowing heat to be conducted from the conductor at the first portion to the exposed portion. The method may further include cutting the electrical wires after the connecting to remove the first portions. Since the flexible member is placed against the exposed conductor, it is difficult to directly heat the exposed conductor. Thus, a method of heating a target conductor portion by heating the first portion near the exposed conductor and allowing heat to be conducted via the conductor can be adopted. In this case, the first portion, which is directly heated, is likely to have a high temperature, and the covering of the electrical wire or the like may be damaged. Thus, by leaving a portion to be a product on the opposite side of the first portion with respect to the exposed conductor, and cutting the first portion after the connecting process, damage to the portion to be a product can be avoided.

(6) A multicore cable according to an embodiment of the present disclosure is a multicore cable including a plurality of electrical wires, and a substrate. The plurality of electrical wires each include a conductor, a covering configured to cover the conductor, and an exposed portion at which the conductor is exposed as a result of the covering being removed. The substrate includes a first surface provided with a plurality of terminals each corresponding to a respective one of the plurality of electrical wires. Each of the terminals and a corresponding one of the exposed portions are electrically connected to each other by solder. Heights of top portions of the conductors of the plurality of electrical wires each connected onto a corresponding one of the terminals are not uniform when the substrate is placed on a horizontal surface such that the first surface faces upward. Conventionally, it has been difficult to connect electrical wires having non-uniform heights to a substrate in a good manner, but according to the present disclosure, a multicore cable in which electrical wires having non-uniform heights are connected to a substrate in a good manner is obtained.

(7) In the above (6), at a leading end of each of the plurality of electrical wires, an end portion of the exposed portion and an end portion of the solder may be formed on an identical plane. An end portion of the electrical wire that is not covered with the solder is formed by cutting the electrical wire after performing soldering. When the electrical wire is heated for performing soldering, the covering or the like of the electrical wire may be damaged by heat. By cutting the electrical wire at the heated portion after performing soldering, damage to the portion to be a product can be avoided.

(8) In the above (6) or (7), the plurality of electrical wires may include electrical wires differing from each other in terms of outer diameters of the conductors. According to the embodiment, the electrical wires having different diameters can be connected to the substrate collectively.

(9) In the above (6) or (7), the first surface of the substrate may include a first region and a second region, and heights of the first region and the second region from the horizontal surface are different each other. The terminals may be provided in each of the first region and the second region. According to the embodiment, even when there is a step or an inclination on the surface of the substrate on which the terminals are arranged, the plurality of electrical wires can be collectively connected.

(10) In the above (9), the first surface of the substrate may include a step.

(11) In the above (9), the first surface of the substrate may be inclined with respect to the horizontal surface.

(12) In the above (9), the first surface of the substrate may include a curved surface.

### Details of Embodiments of Present Disclosure

Specific examples of a multicore cable and a method of manufacturing the multicore cable of the present disclosure will be described below with reference to the drawings. The present invention is not limited to these examples, but is defined by the scope of the claims, and is intended to include all modifications within the meaning and scope equivalent to the scope of the claims. In the drawings, U, D, F, B, R, and L indicate directions in a multicore cable 1, and U indicates upward, D indicates downward, F indicates forward, B indicates backward, R indicates rightward, and L indicates leftward.

### Multicore Cable

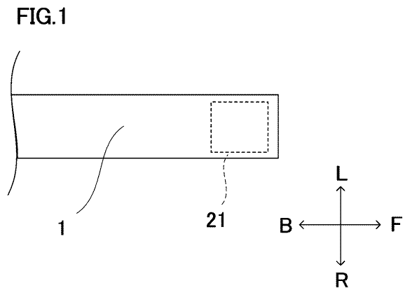

FIG. 1 is a schematic view of the multicore cable 1 according to an embodiment of the present disclosure. As shown in FIG. 1, the multicore cable 1 includes a substrate 21. Only one end of the multicore cable 1 is shown in FIG. 1. The configurations of both ends of the multicore cable 1 may be the same or different.

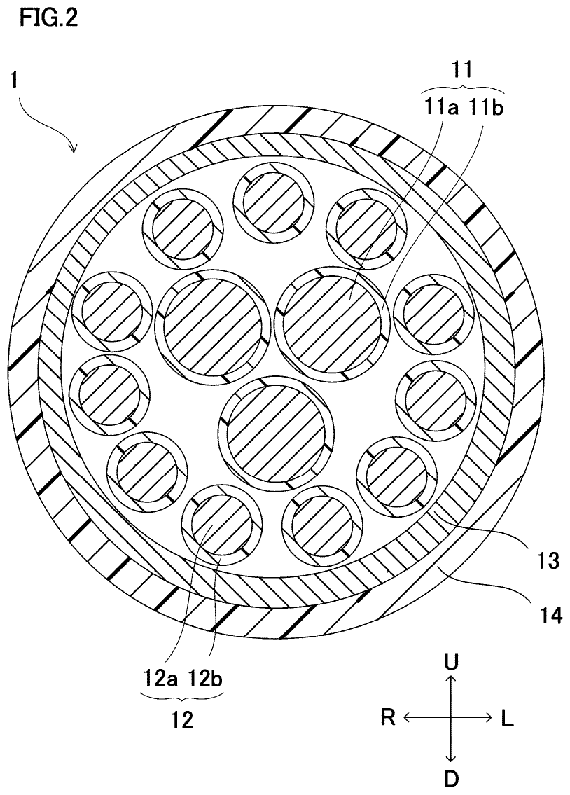

FIG. 2 is a cross-sectional view of the multicore cable 1. As shown in FIG. 2, the multicore cable 1 includes a first electrical wire 11, a second electrical wire 12, a shield layer 13 covering the first electrical wire 11 and the second electrical wire 12, and a cable covering 14 covering the shield layer 13. The multicore cable 1 includes a plurality of first electrical wires 11 and a plurality of second electrical wires 12. The first electrical wire 11 includes a conductor 11a and a covering 11b. The second electrical wire 12 includes a conductor 12a and a covering 12b. As shown in FIG. 2, outer diameters of the conductor 11a and the conductor 12a are different from each other. Thus, outer diameters of the first electrical wire 11 and the second electrical wire 12 are also different from each other. In the following description, when it is not necessary to distinguish the first electrical wire 11 and the second electrical wire 12 from each other, the first electrical wire 11 and the second electrical wire 12 may be simply referred to as electrical wires 11 and 12, respectively.

The conductors 11a and 12a are not particularly limited, and for example, a copper wire, a plated copper wire, or a copper alloy wire can be used. As the conductors 11a and 12a, a single conductor wire or a twisted wire obtained by twisting a plurality of conductor wires may be used. The coverings 11b and 12b are not particularly limited, and an insulating material such as a polyolefin resin, polyurethane, polyimide, perfluoroalkoxy alkane (PFA), or perfluoroethylene propene copolymer (FEP) can be used.

The outer diameter of the conductor 11a may be, for example, 50 μm to 1 mm. The outer diameter of the conductor 12a is smaller than that of the conductor 11a, and may be, for example, 10 μm to 1 mm, 20 μm to 200 μm, 30 μm to 100 μm, or 30 μm to 70 μm. The outer diameters of the conductors 11a and 12a are appropriately selected depending on, for example, the use of the multicore cable 1.

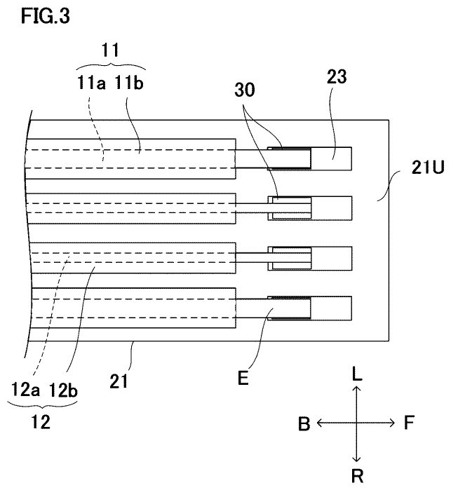

FIG. 3 is a plan view of a connecting portion between the electrical wires 11 and 12 and the substrate 21. Although two first electrical wires 11 and two second electrical wires 12 are shown in FIG. 3, the number of each of the electrical wires 11 and 12 is not particularly limited as long as the number of the first electrical wires 11 and the number of the second electrical wires 12 are each one or more. As shown in FIG. 3, the covering 11b is removed at a front end portion of the first electrical wire 11, and the conductor 11a is exposed. The covering 12b is removed at a front end portion of the second electrical wire 12, and the conductor 12a is exposed. In the present specification, the conductors 11a and 12a exposed at the end portions of the electrical wires 11 and 12 are also referred to as exposed portions E. A plurality of terminals 23 are arranged side by side on an upper surface 21U of the substrate 21. The upper surface 21U corresponds to a first surface of the substrate 21 in the present disclosure. The plurality of terminals 23 each correspond to a respective one of the plurality of electrical wires 11 and 12. As shown in FIG. 3, the exposed portions E of the electrical wires 11, 12 are electrically connected to the terminals 23 corresponding to the electric wires 11 and 12, respectively. The exposed portion E and the terminal 23 are connected to each other by a solder 30.

### Method of Manufacturing Multicore Cable

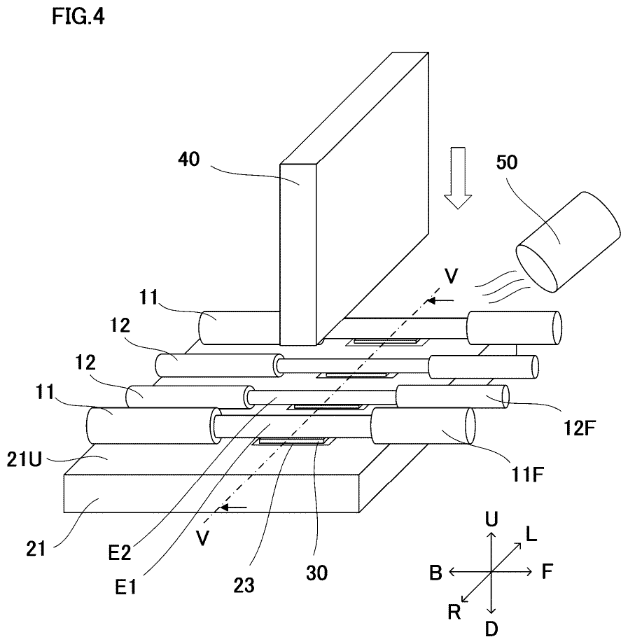

Next, a method of manufacturing a multicore cable according to an embodiment of the present disclosure will be described with reference to the configuration of the multicore cable 1. FIG. 4 is a perspective view showing a process of a method of manufacturing a multicore cable according to an embodiment of the present disclosure. FIG. 4 shows a process of connecting the electrical wires 11 and 12 to the terminals 23 on the substrate 21, the terminals 23 corresponding to the electric wires 11 and 12, respectively. As shown in FIG. 4, two electrical wires 11 and two electrical wires 12 extend in parallel along a forward direction, and one of the first electrical wires 11 are located at the leftmost position, the other of the first electrical wires 11 are located at the rightmost position, and the two second electrical wires 12 are located between the first electrical wires 11. The coverings 11b and 12b are removed from portions of the electrical wires 11 and 12 respectively to form the exposed portions E. Hereinafter, for the sake of description, the exposed portion E of the rightmost first electrical wire 11 may be referred to as an exposed portion E1, and the exposed portion E of the second electrical wire 12 adjacent to the first electrical wire 11 may be referred to as an exposed portion E2.

The method of manufacturing the multicore cable according to the embodiment includes an arranging process and a connecting process. In the arranging process, the exposed portions E of the electrical wires 11 and 12 and the solders 30 are arranged on the plurality of terminals 23 of the substrate 21. In the embodiment shown in FIG. 4, the solder 30 is arranged on the terminal 23, and the exposed portion E is arranged on the solder 30.

Next, in the connecting process, a flexible member 40 is placed against the exposed portions E and pressed toward the substrate 21, while the conductors 11a and 12a are heated by a non-contact method to melt the solder 30 for soldering. In the embodiment shown in FIG. 4, the electrical wires 11 and 12 are heated by applying hot air to the electrical wires 11 and 12 using a hot air blower 50 as a non-contact heating method, and the exposed portions E are heated by heat conduction. In the connecting process, the plurality of terminals 23 and the exposed portions E of the plurality of electrical wires 11 and 12 corresponding to the plurality of terminals 23 are connected to each other collectively.

The role of the flexible member 40 will be further described with reference to FIG. 5. FIG. 5 is a cross-sectional view of the substrate 21 and the electrical wires 11 and 12 taken along line V-V in FIG. 4, and shows a state in which the flexible member 40 is placed against the exposed portions E of the electrical wires 11 and 12 in the connecting process. As shown in FIG. 5, when the substrate 21 is placed on a horizontal surface Sh such that the upper surface 21U of the substrate 21 faces upward, a height H1 from the horizontal surface Sh of a top portion 11T of the exposed portion E1 of the first electrical wire 11 arranged on the terminal 23 is different from a height H2 from the horizontal surface Sh of a top portion 12T of the exposed portion E2 of the second electrical wire 12. That is, the heights of the top portions of the exposed portions E arranged on the terminals 23 are not uniform.

The flexible member 40 can be easily deformed when placed against the exposed portion E. Thus, as shown in FIG. 5, the flexible member 40 may simultaneously contact the exposed portion E1 and the exposed portion E2 having different heights of the top portions, and press the exposed portion E1 and the exposed portion E2 toward the substrate 21. In the state shown in FIG. 5, by performing soldering by heating the conductors 11a and 12a and melting the solders 30, the exposed portions E of the conductors 11a and 12a having different outer diameters can be collectively connected to the plurality of terminals 23 in a good manner.

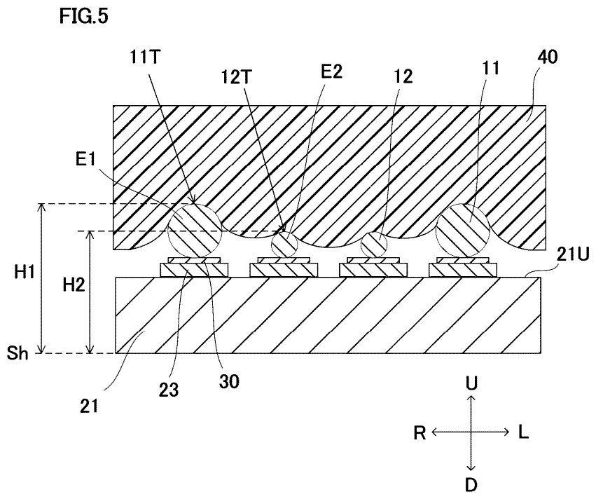

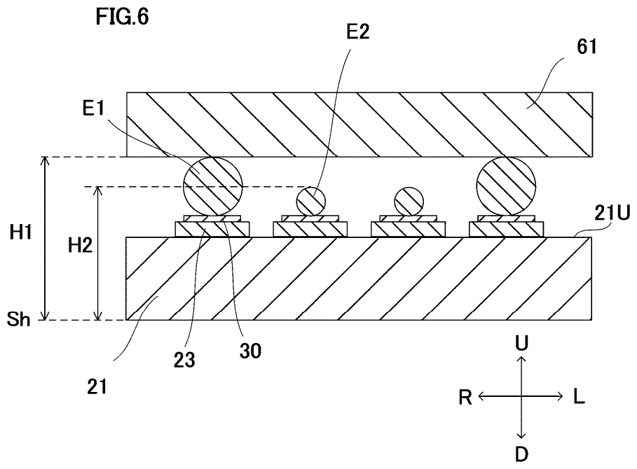

The effects of the method of manufacturing the multicore cable of the present disclosure will be described in more detail with reference to aspects according to comparative examples. FIG. 6 is a diagram showing a connecting process according to a first comparative example, and is a cross-sectional view of a connecting portion with the exposed portions E of the electrical wires 11 and 12 connected to the respective terminals 23, as in FIG. 5. As shown in FIG. 6, in the first comparative example, the electrical wires 11 and 12 are connected to the respective terminals 23 using a heater chip 61. In this aspect, a pulse heating method is adopted in which soldering is performed by heating the electrical wires 11 and 12 while the electrical wires 11 and 12 are pressed toward the substrate 21 by the heater chip 61. However, since the heater chip 61 is typically made of metal or ceramic, it cannot be easily deformed unlike the flexible member 40. Thus, in the case of the present aspect in which there are exposed portion E1 and the exposed portion E2 in which the heights of the top portions are not uniform, as shown in FIG. 6, when the heater chip 61 abuts on the exposed portion E1 in which the height of the top portion is relatively high, the heater chip 61 cannot descend any more, and the exposed portion E2 at a relatively low position and the heater chip 61 do not come into contact with each other. As a result, the exposed portion E2 is not sufficiently pressed and heated, and a connection failure may occur between the exposed portion E2 and the terminal 23.

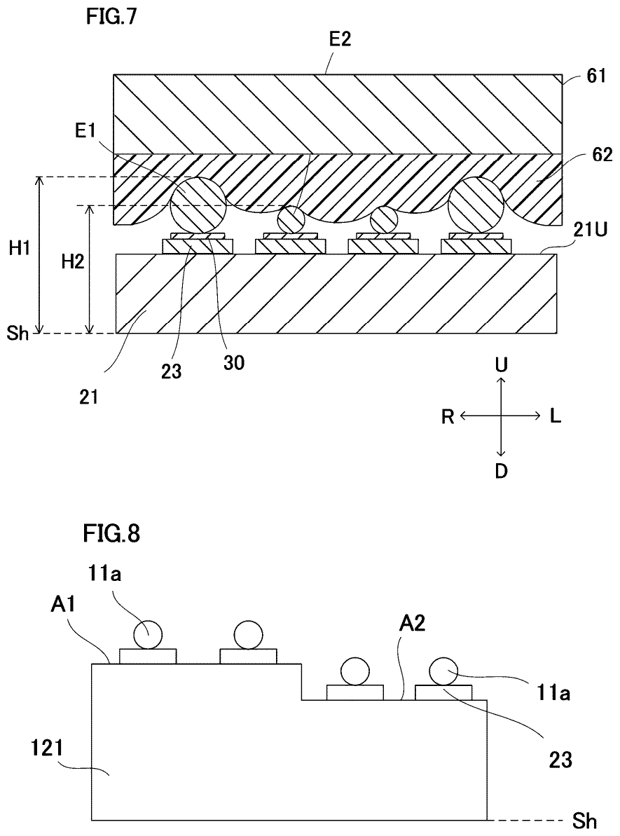

Reference is now made to an aspect according to another comparative example. FIG. 7 is a diagram showing a connecting process according to a second comparative example. In this aspect, a cushion material 62 is disposed between the heater chip 61 and the electrical wires 11 and 12. According to this aspect, unlike the first comparative example described above, the cushion material 62 is easily deformed, and thus the exposed portion E1 and the exposed portion E2 can be simultaneously pressed toward the substrate 21. However, since the cushion material 62 is formed of a material that can be easily deformed but has low thermal conductivity, the heat generated from the heater chip 61 is not easily transferred to the electrical wires 11 or 12. As a result, there is a possibility that the takt time increases and the productivity decreases.

Referring again to the embodiment of the present disclosure shown in FIGS. 4 and 5, according to the present embodiment, the exposed portion E1 and the exposed portion E2 having different heights of the top portions can be simultaneously pressed toward the substrate 21 by the flexible member 40. Furthermore, since the electrical wires are heated by a non-contact method such as hot air, not by a contact method using a heater chip, the takt time is not affected even when the thermal conductivity of the flexible member 40 is low. As described above, according to the embodiment, the plurality of electrical wires whose heights are not uniform can be simultaneously connected to the substrate.

In the embodiment, the substrate 21 may be a hard substrate or a flexible printed circuit (FPC).

The solder 30 may be a low melting point solder. The melting point of the solder 30 may be 180° C. or less, 170° C. or less, 160° C. or less, or 150° C. or less. The lower limit of the melting point of the solder 30 is not particularly limited, but may be, for example, 100° C.

The flexible member 40 is not particularly limited, and may be a plate member formed of a material such as silicone or urethane. A Shore A hardness of the flexible member 40 may be 10° to 70°. A thickness of the flexible member 40 may be 0.2 mm to 1.0 mm.

Examples of the non-contact method of heating the exposed portion E include a method of heating by hot air, a method of heating the conductor by resistance heat by energizing the conductor, and a method of induction heating the conductor by a magnetic field. The heating with hot air facilitates control of the heating range, and damage to surrounding connection members and coverings of the electrical wires, and the like is easily avoided.

The aspect to which the method of manufacturing the multicore cable of the present disclosure is applied is not limited to the case where different-diameter electrical wires are simultaneously connected to a substrate as in the above-described embodiment. Hereinafter, modifications of the configuration of a substrate and an electrical wire to which the method of manufacturing of the present disclosure is applied will be described with reference to the drawings.

FIG. 8 is a diagram showing the configuration of a substrate and an electrical wire according to a first modification. As shown in FIG. 8, in this modification, the plurality of terminals 23 are arranged on a substrate 121, and each of the conductors 11a is connected to each of the plurality of terminals 23. In this modification, the outer diameters of the conductors 11a may be all the same. An upper surface of the substrate 121 has a step, and a first region A1 and a second region A2 having a height from the horizontal surface Sh lower than that of the first region A1 are provided. The terminals 23 are provided in each of the first region A1 and the second region A2. In this modification, although the outer diameters of the conductors 11a are all the same, the terminals 23 are provided in each of the first region A1 and the second region A2 having different heights from the horizontal surface Sh, and thus the heights of the top portions of the conductors 11a provided in the first region A1 and the heights of the top portions of the conductors 11a provided in the second region A2 are different. That is, the heights of the top portions of the conductors 11a arranged on the plurality of terminals 23 are not uniform. In such a configuration, the plurality of terminals 23 and the exposed portions of the corresponding electrical wires can be connected to each other collectively by applying the method of manufacturing the multicore cable of the present disclosure described above.

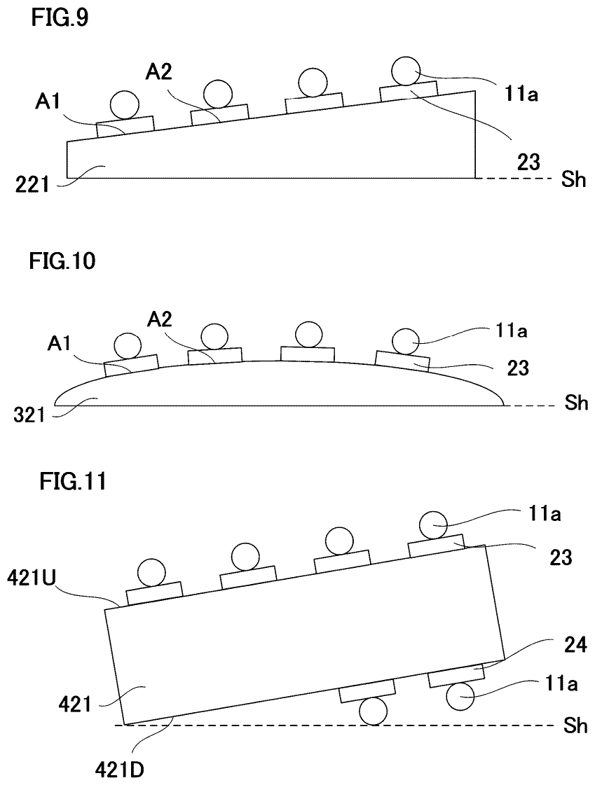

FIG. 9 is a diagram showing a configuration of a substrate and an electrical wire according to a second modification. As shown in FIG. 9, in this modification, an upper surface of a substrate 221 is inclined with respect to the horizontal surface Sh. In this modification, any two regions of the upper surface of the substrate 221 have different heights from the horizontal surface Sh. Thus, for example, as shown in FIG. 9, a portion of the upper surface of the substrate 221 where the leftmost terminal 23 is provided can be regarded as the first region A1, and a portion where the adjacent terminal 23 is provided can be regarded as the second region A2. In this case, the height of the top portion of the conductor 11a provided in the first region A1 is different from the height of the top portion of the conductor 11a provided in the second region A2. That is, the heights of the top portions of the conductors 11a arranged on the plurality of terminals 23 are not uniform. In such a configuration, the plurality of terminals 23 and the exposed portions of the corresponding electrical wires can be connected to each other collectively by applying the method of manufacturing the multicore cable of the present disclosure described above.

FIG. 10 is a diagram showing a configuration of a substrate and an electrical wire according to a third modification. As shown in FIG. 10, in this modification, an upper surface of a substrate 321 is a curved surface. In this modification, for example, a portion where the leftmost terminal 23 is provided can be regarded as the first region A1, and a portion where the adjacent terminal 23 is provided can be regarded as the second region A2. In this case, the height of the top portion of the conductor 11a provided in the first region A1 is different from the height of the top portion of the conductor 11a provided in the second region A2. That is, the heights of the top portions of the conductors 11a arranged on the plurality of terminals 23 are not uniform. In such a configuration, the plurality of terminals 23 and the exposed portions of the corresponding electrical wires can be connected to each other collectively by applying the method of manufacturing the multicore cable of the present disclosure described above. In the example shown in FIG. 10, the entire upper surface of the substrate 321 is a curved surface, but the present disclosure can be similarly applied to a configuration in which the upper surface of the substrate partially has a curved surface and terminals are arranged on the curved surface.

FIG. 11 is a diagram showing a configuration of a substrate and an electrical wire according to a fourth modification. As shown in FIG. 11, in this modification, a connecting portion between the conductor 11a and a terminal 24 is arranged on a lower surface 421D of a substrate 421. Thus, in this modification, although an upper surface 421U of the substrate 421 is flat and the outer diameters of electrical wires are the same, when the substrate 421 is placed on the horizontal surface Sh with the upper surface 421U facing upward, the heights of the top portions of the conductors 11a arranged on the plurality of terminals 23 on the upper surface 421U are not uniform. In such a configuration, the plurality of terminals 23 and the exposed portions of the corresponding electrical wires can be connected to each other collectively by applying the method of manufacturing the multicore cable of the present disclosure described above. Components arranged on the lower surface 421D are not limited to the conductor 11a or the terminal 24, and may be any member. In this modification, the lower surface 421D is flat, but the lower surface 421D may have a step, an inclined surface, or a curved surface, as in the upper surface of the substrate in the first modification to the third modification described above.

In addition, in the method of manufacturing the multicore cable of the present disclosure, heating of the exposed portions by the non-contact method may be performed by heating a first portion of each of the electrical wires extending from the exposed portion in a first direction, and allowing heat to be conducted from the conductor at the first portion to the exposed portion, and the method may further include a cutting process of cutting the first portion after the connecting process. For example, in the configuration shown in FIG. 4, a forward direction corresponds to the first direction, and a portion 11F of the electrical wires 11 and a portion 12F of the electrical wire 12 each correspond to the first portion, the portions 11F and 12F extending from the exposed portions E in the forward direction. As shown in FIG. 4, the hot air blower 50 heats first portions 11F and 12F, and heats the exposed portions E (exposed portions E1 and E2) by allowing heat to be conducted from the conductors 11a and 12a at the first portions 11F and 12F to the exposed portions E. Although FIG. 4 shows a state in which the coverings are left on the first portions 11F and 12F to be heated, the coverings on the first portions 11F and 12F to be heated may be removed. In the cutting process after the connecting process, the electrical wires 11 and 12 are cut at a position of the line V-V in FIG. 4, for example, to remove the first portions 11F and 12F. By the cutting process, at a leading end of each of the plurality of electrical wires 11 and 12, an end portion of the exposed portion E and an end portion of the solder 30 are formed on an identical plane as shown in FIG. 3, for example. The expression “formed on an identical plane” here should be understood as meaning that cut surfaces obtained by cutting the electrical wires 11 and 12 and the solder 30 together at a predetermined position as described above are formed, and does not necessarily mean that the cut surfaces of the solder 30 and the end portions of the electrical wires 11 and 12 are formed on the completely same plane.

Since the flexible member 40 is placed against the exposed portions E, it is difficult to directly heat the exposed portions E. Thus, a method of heating the exposed portions E by heating the first portions 11F and 12F near the exposed portions E and allowing heat to be conducted via the conductors 11a and 12a can be adopted. In this case, the first portions 11F and 12F, which are directly heated, are likely to have a high temperature, and the coverings 11b and 12b of the electrical wires 11 and 12 may be damaged. Thus, by leaving portions to be products on the opposite sides of the first portions 11F and 12F with respect to the exposed portions E, and cutting the first portions 11F and 12F after the connecting process, damage to the portions to be products can be avoided.

The present disclosure also relates to the multicore cable described above. That is, the multicore cable 1 according to the embodiment of the present disclosure includes the plurality of electrical wires 11 and 12 and the substrate 21. The plurality of electrical wires 11 and 12 each include the conductor 11a or 12a, the covering 11b or 12b covering the conductor 11a or 12a, and the exposed portion E at which the conductor 11a or 12a is exposed as a result of the covering 11b or 12b being removed. The first surface 21U of the substrate 21 is provided with the plurality of terminals 23 each corresponding to a respective one of the plurality of electrical wires 11 and 12. Each of the terminals 23 and a corresponding one of the exposed portions E are electrically connected to each other by the solder 30. The heights of the top portions 11T and 12T of the conductors 11a and 12a of the plurality of electrical wires 11 and 12 each connected onto a corresponding one of the terminals 23 are not uniform when the substrate 21 is placed on the horizontal surface Sh such that the first surface 21U faces upward.

In the multicore cable 1 of the embodiment, at the leading ends of the plurality of electrical wires 11 and 12, an end portion of the exposed portion E and an end portion of the solder 30 may be formed on an identical plane. An end portion of the electrical wire that is not covered with solder is formed by cutting the electrical wire after performing soldering. When the electrical wire is heated for performing soldering, the covering or the like of the electrical wire may be damaged by heat. By cutting the electrical wire at the heated portion after performing soldering, damage to the portion to be a product can be avoided.

Although the method of manufacturing the multicore cable and the multicore cable of the present disclosure have been described with reference to specific embodiments, the present disclosure is not limited to these embodiments.

In the above description, the example in which the electrical wire is an insulated electrical wire including the conductor and the covering has been described, but the electrical wire is not limited to the insulated electrical wire, and may be, for example, a coaxial electrical wire. In addition, although the example in which the plurality of electrical wires are each covered with the shield layer and the cable covering has been described, the shield layer and the cable covering are not essential in the present disclosure. That is, the multicore cable of the present disclosure may be a cable in which the electrical wire is exposed without including the shield layer and the cable covering.

In the above description, the example in which the shape of the substrate in a plan view is a rectangle is shown, but the shape of the substrate is not particularly limited, and may be a polygonal shape or a shape in which at least a part of the side surface is a curved surface.

What is claimed is:

1. A method of manufacturing a multicore cable including a plurality of electrical wires and a substrate,
the plurality of electrical wires each including a conductor, a covering configured to cover the conductor, and an exposed portion at which the conductor is exposed as a result of the covering being removed,
the substrate including a first surface provided with a plurality of terminals each corresponding to a respective one of the plurality of electrical wires,
heights of top portions of the exposed portions each arranged on a corresponding one of the terminals being not uniform when the substrate is placed on a horizontal surface such that the first surface faces upward,
the method comprising:
arranging the exposed portions and solder on the plurality of terminals; and
connecting the plurality of terminals and the exposed portions of the plurality of electrical wires corresponding to the plurality of terminals to each other collectively by, while placing a flexible member against the exposed portions and pressing the flexible member toward the substrate, performing soldering by heating the conductors by a non-contact method and melting the solder.

2. The method of manufacturing the multicore cable according to claim 1,
wherein the plurality of electrical wires include a plurality of electrical wires differing from each other in terms of outer diameters of the conductors.

3. The method of manufacturing the multicore cable according to claim 1,
wherein the first surface of the substrate includes a first region and a second region differing from each other in terms of heights of the first region and the second region from the horizontal surface,
wherein the terminals are provided in each of the first region and the second region, and
wherein, in the connecting, the exposed portions of the plurality of electrical wires each corresponding to a respective one of the terminals are collectively connected to the terminals provided in the first region and the terminals provided in the second region.

4. The method of manufacturing the multicore cable according to claim 1,
wherein the non-contact method is heating with hot air.

5. The method of manufacturing the multicore cable according to claim 1,
wherein heating of each of the exposed portions by the non-contact method is performed by heating a first portion of each of the electrical wires extending from the exposed portion in a first direction, and allowing heat to be conducted from the conductor at the first portion to the exposed portion, and
wherein the method further comprises cutting the electrical wires after the connecting to remove the first portions.

6. A multicore cable comprising:
a plurality of electrical wires; and
a substrate,
wherein the plurality of electrical wires each include a conductor, a covering configured to cover the conductor, and an exposed portion at which the conductor is exposed as a result of the covering being removed,
wherein the substrate includes a first surface provided with a plurality of terminals each corresponding to a respective one of the plurality of electrical wires,
wherein each of the terminals and a corresponding one of the exposed portions are electrically connected to each other by solder, and
wherein heights of top portions of the conductors of the plurality of electrical wires each connected onto a corresponding one of the terminals are not uniform when the substrate is placed on a horizontal surface such that the first surface faces upward.

7. The multicore cable according to claim 6,
wherein, at a leading end of each of the plurality of electrical wires, an end portion of the exposed portion and an end portion of the solder are formed on an identical plane.

8. The multicore cable according to claim 6,
wherein the plurality of electrical wires include electrical wires differing from each other in terms of outer diameters of the conductors.

9. The multicore cable according to claim 6,
wherein the first surface of the substrate includes a first region and a second region, heights of the first region and the second region from the horizontal surface are different from each other, and
wherein the terminals are provided in each of the first region and the second region.

10. The multicore cable according to claim 9,
wherein the first surface of the substrate includes a step.

11. The multicore cable according to claim 9,
wherein the first surface of the substrate is inclined with respect to the horizontal surface.

12. The multicore cable according to claim 9,
wherein the first surface of the substrate includes a curved surface.
